(19) United States
(12) Patent Application Publication
(10) Pub. No.: US 2015/0070027 A1
(43) Pub. Date: Mar. 12, 2015

(54) METHOD AND APPARATUS FOR DETECTING DISCONNECTION OF THREE-PHASE CABLE

(71) Applicant: HYUNDAI MOTOR COMPANY, Seoul (KR)

(72) Inventors: Heon Young Kwak, Hwaseong (KR); Jong Kyong Lim, Seongnam (KR); Ju Man Yoon, Seoul (KR)

(73) Assignee: HYUNDAI MOTOR COMPANY, Seoul (KR)

(21) Appl. No.: 14/264,609

(22) Filed: Apr. 29, 2014

(30) Foreign Application Priority Data
Sep. 12, 2013 (KR) 10-2013-0110023

(51) Int. Cl. G01R 31/04

(52) U.S. Cl. CPC G01R 31/043
USPC 324/538

(57) ABSTRACT

A method and an apparatus for detecting disconnection from three-phase cable are provided. The method includes switching a plurality of switching elements included within switching units each corresponding to the respective phases of three-phase circuits configuring an output stage based on a predetermined criteria. In addition, the method includes applying a current generated in an input stage to the switching elements determined to be switched on and off based on the switching and detecting a current flow from the plurality of switching elements based on the applied current. Further, which of the three-phase circuits at the output stage is an open phase is determined based on the detection result.

### CROSS REFERENCE TO RELATED APPLICATION

This application claims the benefit of Korean Patent Application No. 10-2013-0110023, filed on Sep. 12, 2013, entitled “Method and apparatus for detecting disconnection of 3-phase cable”, which is hereby incorporated by reference in its entirety into this application.

### BACKGROUND

1. Technical Field

The present invention relates to a method and an apparatus that detect a disconnection of a three-phase cable, and more particularly, to a method and an apparatus for detecting disconnection of a three-phase cable that detect which three-phase cable is disconnected by performing switching one time.

2. Description of the Related Art

Generally, three-phase motors are required for operating hybrid vehicles. Although vehicles may have different systems, it is common that motors are used for driving a vehicle and charging a battery. In particular, direct-current (DC) voltage from a battery is delivered to a three-phase motor via an inverter that converts the DC voltage into alternating-current (AC) voltage to drive the motor. Since three-phase cables that transfer power between the output of the inverter and the input of the motor are generally located within an engine room, the cables may be exposed to environmental influence such as varying temperature, humidity and external impact. Therefore, damage to the cables may occur causing disconnection of the cables. When even one of the three-phase cables is disconnected, the three-phase motor may not be controlled normally (e.g., without error or failure) causing the motor to become unpredictable and increasing driver danger.

### SUMMARY

The present invention provides a method and an apparatus for detecting disconnection of three-phase cables that may determine in which of phases disconnection occurs by switching the switching elements connected to the three-phase cables one time.

According to an exemplary embodiment of the present invention, a method for detecting disconnection of a three-phase cable may include: switching a plurality of switching elements within switching units each corresponding to the respective phases of three-phase circuits configuring an output stage based on a predetermined criteria; applying a current generated in an input stage to the switching elements determined to be switched on and off based on the switching; detecting current flow from the plurality of switching elements based on the applied current; and determining, by a processor, which of the three-phase circuits at the output stage is in an open phase based on the detecting result.

Furthermore, the switching may be performed one time. The method may be performed when a vehicle is started or a brake pedal of the vehicle is engaged. The determination of the disconnected three-phase circuit may include determining that one of the three-phase circuits is an open phase when no current flow is detected from the plurality of the switching elements. In addition, the determination may include determining that any one phase is an open phase when current flow is detected from the switching elements connected to two of the three-phase circuits. The determination may also include determining that one phase is an open phase from which no current flow is detected when current flow is detected from the switching elements connected to two of the three-phase circuits.

The three-phase circuits may include first, second and third phases, each of the three switching units connected to the first, second and third phases may include an upper switching element and a lower switching element. The switching may include switching on the upper switching element connected to the first phase, the lower switching element connected to the second phase, and the lower switching element connected to the third phase.

Additionally, the determination of the disconnected three-phase circuits may include: determining that the first phase is an open phase when no current flow is detected from any of the switching elements; determining that the second phase is an open phase when no current flow is detected from the switching unit connected to the second phase; and determining that the third phase is an open phase when no current flow is detected from the switching unit connected to the third phase.

According to another exemplary embodiment of the present invention, an apparatus for detecting disconnection of a three-phase cable, may include: three-phase circuits operating as an output stage; switching units that each correspond to the respective phases of the three-phase circuits; a plurality of switching elements included within the switching units and switched based on a predetermined criteria; an input stage applying generated current to the switching elements determined to be switched on and off based on the switching; a detecting unit configured to detect current flow from the plurality of switching elements based on the applied current; and a determining unit (e.g., a processor) configured to determine which of the three-phase circuits at the output stage is an open phase based on the detecting result.

The three-phase circuits may include first, second and third phases, each of the three switching units connected to the first, second and third phases may include an upper switching element and a lower switching element. The upper switching element connected to the first phase, the lower switching element connected to the second phase, and the lower switching element connected to the third phase may be switched on. In addition, determining unit may be configured to determine that the first phase is an open phase when no current flow is detected from any of the switching elements, determine that the second phase is an open phase when no current flow is detected from the switching unit connected to the second phase only, and determine that the third phase is an open phase when no current flow is detected from the switching unit connected to the third phase only.

### BRIEF DESCRIPTION OF THE DRAWINGS

The above and other objects, features and advantages of the present invention will be more clearly understood from the following detailed description taken in conjunction with the accompanying drawings, in which:

FIG. 1 is an exemplary table illustrating current flows in switching elements connected to phases of a three-phase cable when one of the phases is an open phase according to an exemplary embodiment of the present invention;

FIG. 2 is an exemplary view illustrating an apparatus for detecting disconnection of a three-phase cable according to an exemplary embodiment of the present invention;

FIG. 3A to 3C are exemplary views illustrating a process for detecting disconnection of a three-phase cable according to an exemplary embodiment of the present invention; and

FIG. 4 is an exemplary flowchart illustrating a method for detecting disconnection of a three-phase cable according to an exemplary embodiment of the present invention.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

Although exemplary embodiment is described as using a plurality of units to perform the exemplary process, it is understood that the exemplary processes may also be performed by one or plurality of modules. Additionally, it is understood that the term controller/control unit refers to a hardware device that includes a memory and a processor. The memory is configured to store the modules and the processor is specifically configured to execute said modules to perform one or more processes which are described further below.

Furthermore, control logic of the present invention may be embodied as non-transitory computer readable media on a computer readable medium containing executable program instructions executed by a processor, controller/control unit or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/of” includes any and all combinations of one or more of the associated listed items.

Specific descriptions on structure and function of exemplary embodiments of the present invention described herein are merely illustrative and not construed to limit the invention thereto. Since the present invention may be variously modified and have several exemplary embodiments, specific exemplary embodiments will be shown in the accompanying drawings and be described in detail. However, it is to be understood that the present invention is not limited to the specific exemplary embodiments, but includes all modifications, equivalents, and substitutions included in the spirit and the scope of the present invention.

Terms such as ‘first’, ‘second’, etc., may be used to describe various components, but the components are not to be construed as being limited to the terms. The terms are used only to distinguish one component from another component. For example, the ‘first’ component may be named the ‘second’ component and the ‘second’ component may also be similarly named the ‘first’ component, without departing from the scope of the present invention.

It is to be understood that when one element is referred to as being “connected to” or “coupled to” another element, it may be connected directly to or coupled directly to another element or be connected to or coupled to another element, having the other element intervening therebetween. On the other hand, it is to be understood that when one element is referred to as being “connected directly to” or “coupled directly to” another element, it may be connected to or coupled to another element without the other element intervening therebetween. Other expressions describing a relationship between components, that is, “between,” “directly between,” “neighboring to,” “directly neighboring to” and the like, should be similarly interpreted.

Terms used in the present specification are used only in order to describe specific exemplary embodiments rather than limiting the present invention. Singular forms used herein are intended to include plural forms unless explicitly indicated otherwise. It will be further understood that the terms “comprises” or “have” used in this specification, specify the presence of stated features, steps, operations, components, parts, or a combination thereof, but do not preclude the presence or addition of one or more other features, numerals, steps, operations, components, parts, or a combination thereof.

Unless indicated otherwise, it is to be understood that all the terms used in the specification including technical and scientific terms have the same meaning as those that are understood by those who skilled in the art. It must be understood that the terms defined by the dictionary are identical with the meanings within the context of the related art, and they should not be ideally or excessively formally defined unless the context clearly dictates otherwise.

Hereinafter, preferred embodiments of the present invention will be described in detail with reference to the accompanying drawings. Like reference numerals denote like components throughout the drawings.

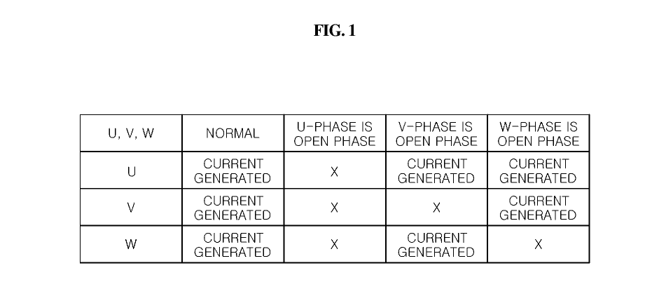

FIG. 1 is an exemplary table illustrating current flows in switching elements connected to phases of a three-phase cable when one of the phases is an open phase according to an exemplary embodiment of the present invention. Referring to FIG. 1, when all of the phases of the three-phase cable are normally connected (e.g., when none of the phases are disconnected), currents may be generated in all of the switching elements connected to the three-phase cable. In other words, when U-phase, V-phase and W-phase cables are normally connected (e.g., not disconnected), current flows in the switching elements connected to the U-phase, V-phase and W-phase.

In addition, when the U-phase of the three-phase cable is an open phase, no current flows in the switching elements connected to the U-phase, V-phase and W-phase cables. When the V-phase is an open phase, currents flow in the switching elements connected to the U-phase and the W-phase but no current flows in the switching element connected to the V-phase. When the W-phase is an open phase, currents flow in the switching elements connected to the U-phase and the V-phase but no current flows in the switching element connected to the W-phase.

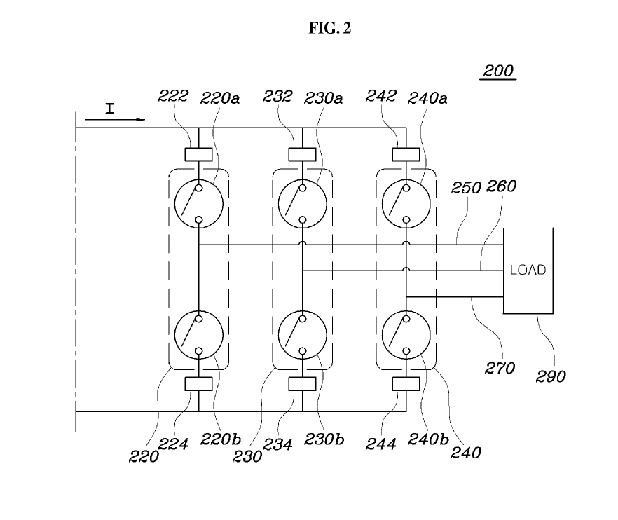

FIG. 2 is an exemplary view illustrating an apparatus for detecting disconnection of a three-phase cable according to an exemplary embodiment of the present invention. The apparatus 200 may include a three-phase cable 250, 260 and 270; switching units 220, 230 and 240 connected to the respective phases of a three-phase circuits 250, 260 and 270; a plurality of switching elements 220a, 220b, 230a, 230b, 240a and 240b included within the switch units 220, 230 and 240 to be switched based on a predetermined criteria; an input terminal (not shown) to apply a generated current I to the switching elements 220a, 220b, 230a, 230b, 240a and 240b which have been switched on and off based on switching; detecting units (e.g., sensors) 222, 224, 232, 234, 242 and 244 configured to detect a current flow from the plurality of switching elements 220a, 220b, 230a, 230b, 240a and 240b based on the applied current I; and a determining unit or a processor (not shown) configured to determine an open circuit from among the three-phase circuits 250, 260 and 270 at an output stage based on the detection result in the detecting units 222, 224, 232, 234, 242 and 244. The three-phase circuits 250, 260 and 270 may be connected to a load 290.

Specifically, the three-phase circuits 250, 260 and 270 may include a U-phase cable 250, a V-phase cable 260, and a W-phase cable 270 and the U-phase cable 250 may be connected to the first switching unit 220. The first switching unit 220 may include an upper switching element 220a and a lower switching element 220b and may include detecting units 222 and 224 disposed near (e.g., adjacent to) the switching elements 220a and 220b, respectively, to detect current flow in the corresponding switching elements. When the upper switching element 220a is switched on and when a path exists via which current may return from the load, the input current I may pass through the upper switching element 220a connected to the U-phase cable 250 to enter the load.

The V-phase cable 260 may be connected to the second switching unit 230. The second switching unit 230 may include an upper switching element 230a and a lower switching element 220b and may include detecting units 232 and 234 disposed near (e.g., adjacent to) the switching elements 230a and 230b, respectively, to detect current flow in the corresponding switching elements. When the upper switching element 230a is switched on and when a path exists via which current may return from the load, the input current I may pass through the upper switching element 230a connected to the V-phase cable 260 to enter the load. In addition, the W-phase cable 270 may be connected to the third switching unit 240. The third switching unit 240 may include an upper switching element 240a and a lower switching element 240b and may include detecting units 242 and 244 disposed near (e.g., adjacent to) the switching elements 240a and 240b, respectively, to detect current flow in the corresponding switching elements. When the upper switching element 240a is switched on and when a path exists via which current may return from the load, the input current I may pass through the upper switching element 240a connected to the W-phase cable 270 to enter the load.

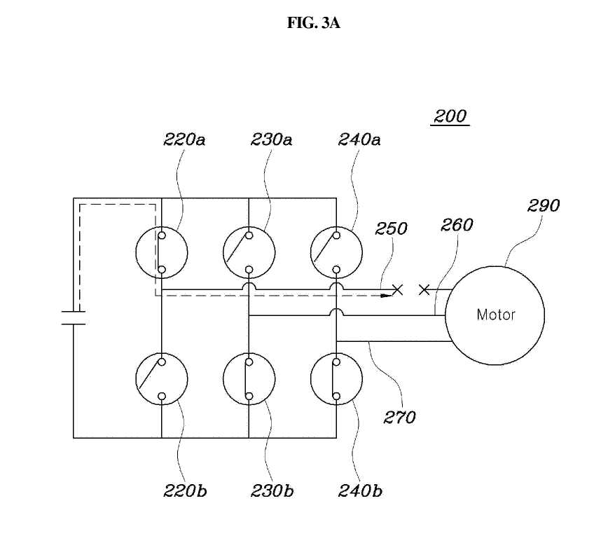

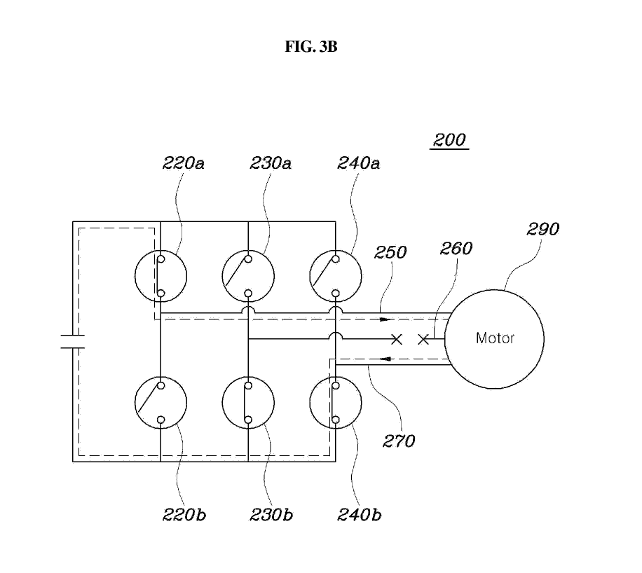

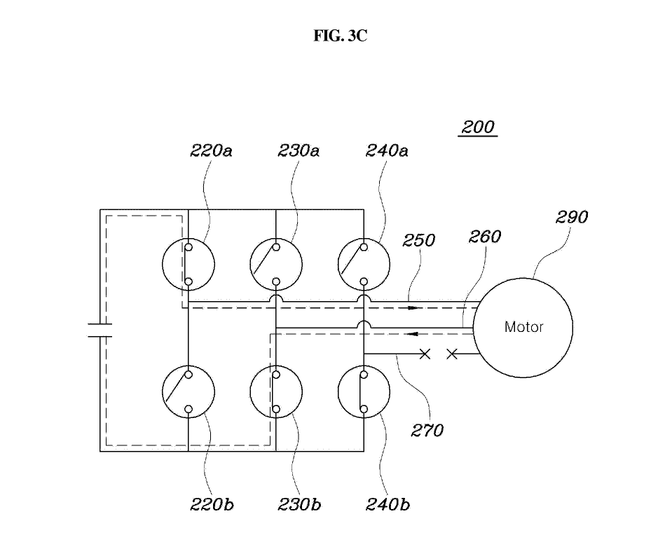

FIG. 3A to 3C are exemplary views illustrating a process for detecting disconnection of a three-phase cable according to an exemplary embodiment of the present invention. A plurality of switching elements 220a, 220b, 230a, 230b, 240a and 240b included within the switching units 220, 230 and 240 may each correspond to the respective phases of the three-phase circuits 250, 260 and 270. Connection states of the plurality of switching elements may be set one time (e.g., avoiding multiple adjustments), to determine whether disconnections are present in the three-phase cable 250, 260 and 270 in the set switching state.

In particular, with regards to the switching states of the switching elements 220a, 220b, 230a, 230b, 240a and 240b, an upper switching element 220a connected to the U-phase cable 250, a lower switching element 230b connected to the V-phase cable 260, and a lower switching element 240b connected to the W-phase cable 270 may be switched on to close the switching elements, while a lower switching element 220b connected to the U-phase cable 250, an upper switching element 230a connected to the V-phase cable 260, and an upper switching element 240a connected to the W-phase cable 270 may be switched off to open the switching elements.

Referring to FIG. 3A in which the U-phase cable 250 is disconnected, the switching element 220a may be switched on and the U-phase cable 250 may be disconnected to prevent an input current I from flowing in the upper switching element 220a. Since no current is input to the load, (i.e., a motor) no current flows in any of the switching elements connected to the U-phase, V-phase, and W-phase 250, 260 and 270.

As a result, when no current flow is detected from the plurality of switching elements 220a, 220b, 230a, 230b, 240a and 240b, the U-phase cable 250 among the three-phase cable 250, 260 and 270 may be determined to be an open phase. In other words, when no current is detected in any of the switching elements upon the input current I being applied, the U-phase cable 250 may be determined to be disconnected. In addition, when current flow is detected from the switching elements connected to two phases of the three-phase cable 250, 260 and 270, any one of the phases may be determined to be an open phase. When current flow is detected from the switching elements connected to two phases of the three-phase cable 250, 260 and 270, the one phase from which no current flow is detected may be determined to be an open phase.

In particular, referring to FIG. 3B in which the V-phase cable 260 is disconnected, since only the switching element 220a that is connected to the U-phase 250 is switched on, the input current I may enter the load through the U-phase cable 250. Although the V-phase cable 260 is disconnected, the W-phase cable 270 may connect the load to the input terminal and the current entering the load through the U-phase cable 250 may flow to the input terminal through the W-phase cable 270. Accordingly, current may flow through the upper switching element 220a connected to the U-phase cable 250 and the lower switching element 240b connected to the W-phase cable 270, and such current flow may be detected by the detecting units 222 and 224 to determine that the V-phase cable 260 is disconnected.

Further, referring to FIG. 3C in which the W-phase cable 270 is disconnected, since only the switching element 220a that is connected to the U-phase cable 250 is switched on, the input current I may enter the load through the U-phase cable 250. Although the W-phase cable 270 is disconnected, the V-phase cable 260 may connect the load to the input terminal and the current entering the load through the U-phase cable 250 may flow to the input terminal through the V-phase cable 260.

Accordingly, current may flow through the upper switching element 220a connected to the U-phase cable 250 and the lower switching element 230b connected to the V-phase cable 260, and the current flow may be detected by the detecting units 222 and 234 to determine that the W-phase cable 270 is disconnected. In other words, when no current flow is detected in any of the switching elements 220a, 220b, 230a, 230b, 240a and 240b, the U-phase cable 250 may be determined to be disconnected and that the U-phase is an open phase. When no current flow is detected in the switching units 230a and 230b connected to the V-phase cable 260, the V-phase cable 260 may be determined to disconnected and that the V-phase is an open phase. In addition, when no current flow is detected in the switching units 240a and 240b connected to the W-phase cable 270, the W-phase cable 270 may be determined to be disconnected and that the W-phase is an open phase.

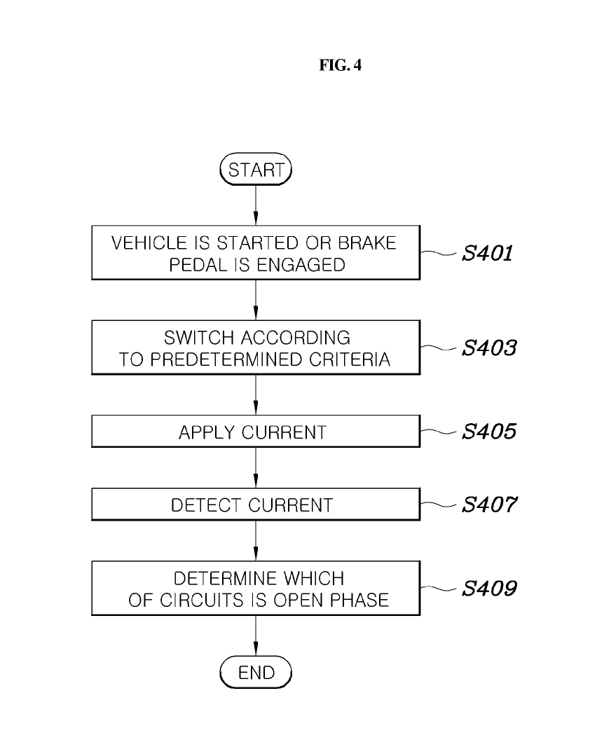

FIG. 4 is an exemplary flowchart illustrating a method for detecting disconnection of a three-phase cable according to an exemplary embodiment of the present invention. Referring to FIG. 4, the method for detecting disconnection of a three-phase cable may include: when a vehicle enters the ignition (IG) on state or a braking state, that is, when the vehicle is started or a brake pedal is engaged (S401), as shown in FIGS. 3A to 3C, the connection states of the switching elements 220a, 220b, 230a, 230b, 240a and 240b may be connected to the three-phase cable 250, 260 and 270 (S403). In other words, the upper switching element 220a connected to the U-phase cable 250, a lower switching element 230b connected to the V-phase cable 260, and a lower switching element 240b connected to the W-phase cable 270 may be switched on, while a lower switching element 220b connected to the U-phase cable 250, an upper switching element 230a connected to the V-phase cable 260, and an upper switching element 240a connected to the W-phase cable 270 may be switched off.

When the input current I is applied to a circuit having the set switching (e.g., set only once) (S405), the applied current I may be detected in the corresponding switching elements among the detecting units (e.g., sensors) 222, 224, 232, 234, 242 and 244 connected to the U-phase cable 250, the V-phase cable 260 and the W-phase cable 270 based on which of the U-phase cable 250, the V-phase cable 260 and the W-phase cable 270 is disconnected (S407). Based on the detection result of current flow in the switching elements, the determining unit (e.g., the processor) may be configured to determine that which of the three-phase cable is an open phase.

In the conventional structure, three individual tests were necessary to determine in which of the phases the cable was in an open phase. In contrast, according to an exemplary embodiment of the present invention, by switching on the upper switching element 220a and switching off the lower switching element 220b connected to the U-phase cable 250, switching off the upper switching element 230a and switching on the lower switching element 230b connected to the V-shape cable 260, and switching off the upper switching element 240a and switching on the lower switching element 240b connected to the W-phase cable 270, it may be possible to determine which of the three-phase cable 250, 260 and 270 is an open phase at one time, thus preventing multiple adjustments. Therefore, the time consumed to detect disconnection may be reduced, and thus the degree of freedom of applying disconnection detecting may be increased.

According to an exemplary embodiment, when a vehicle is turned on or when a brake pedal is engaged, the algorithm to detect disconnection of a three-phase cable may be initiated. In response to determining that one of the cables among the three-phase cable connected to a motor is disconnected, the motor may no longer be operable, and therefore the vehicle may enter an engine driving mode in which an engine is driven instead or a service lamp may be lit to notify the driver of the failure. When the service lamp is lit, the driver may become aware that one of the three-phase cable connected to the motor is disconnected and that the motor has failed.

Although the present invention has been described with reference to the exemplary embodiment shown in the drawings, they are merely illustrative. It will be appreciated by those skilled in the art that various modifications and equivalent other embodiments are possible from the present invention. Accordingly, the true technical protection scope of the present invention must be defined by the spirit of the accompanying claims.

What is claimed is:

1. A method for detecting disconnection of a three-phase cable, the method comprising:
operating, by a processor, a plurality of switching elements included within switching units each corresponding to respective phases of three-phase circuits configuring an output stage to switch the plurality of switching elements based on a predetermined criteria;
operating, by the processor, the switching units to apply a current generated in an input stage to the switching elements determined to be switched on and off based on the switching;
detecting, by a sensor, a current flow from the plurality of switching elements based on the applied current; and
determining, by the processor, which of the three-phase circuits at the output stage is an open phase based on the detection result.

2. The method according to claim 1, wherein the switching is performed one time.

3. The method according to claim 1, wherein the method is performed when a vehicle is started or a brake pedal of the vehicle is engaged.

4. The method according to claim 1, wherein the open phase determination includes:
determining, by the processor, that one of the three-phase circuits is an open phase when no current flow is detected from the plurality of the switching elements.

5. The method according to claim 1, wherein the open phase determination includes:
determining, by the processor, that one of the phases is an open phase when the current flow is detected from the switching elements connected to two of the three-phase circuits.

6. The method according to claim 1, wherein the open phase determination includes:
determining, by the processor, that one phase is an open phase from which no current flow is detected when the current flow is detected from the switching elements connected to two of the three-phase circuits.

7. The method according to claim 1, wherein the three-phase circuits include first, second and third phases, each of the three switching units connected to the first, second and third phases includes an upper switching element and a lower switching element, and the switching includes switching on the upper switching element connected to the first phase, the lower switching element connected to the second phase, and the lower switching element connected to the third phase.

8. The method according to claim 7, wherein the open phase determination includes:
determining, by the processor, that the first phase is an open phase when no current flow is detected from the switching elements;
determining, by the processor, that the second phase is an open phase when no current flow is detected from the switching unit connected to the second phase; and
determining, by the processor, that the third phase is an open phase when no current flow is detected from the switching unit connected to the third phase.

9. An apparatus for detecting disconnection of a three-phase cable, the apparatus comprising:
three-phase circuits configuring an output stage;
switching units each corresponding to the respective phases of the three-phase circuits;
a plurality of switching elements included within the switching units and switched based on a predetermined criteria;
an input stage configured to apply generated current to the switching elements determined to be switched on and off based on the switching;
a sensor configured to detect a current flow from the plurality of switching elements based on the applied current; and
a processor configured to determine which of the three-phase circuits at the output stage is an open phase based on the detection result.

10. The apparatus according to claim 9, wherein the three-phase circuits include first, second and third phases, each of the three switching units connected to the first, second and third phases includes an upper switching element and a lower switching element, and the upper switching element connected to the first phase, the lower switching element connected to the second phase, and the lower switching element connected to the third phase are switched on.

11. The apparatus according to claim 9, wherein the processor is configured to:
determine that the first phase is an open phase when no current flow is detected from the switching elements,
determine that the second phase is an open phase when no current flow is detected from the switching unit connected to the second phase, and
determine that the third phase is an open phase when no current flow is detected from the switching unit connected to the third phase.
